(19) United States
(12) Patent Application Publication
(10) Pub. No.: US 2026/0333803 A1
(43) Pub. Date: Oct. 22, 2026

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Chung-En TSAI, Hsinchu (TW); Sheng-Syun WONG, Hsinchu (TW); Cheng-Han LEE, New Taipei (TW); Chih-Yu MA, Hsinchu (TW); Shih-Chieh CHANG, Taipei (TW); Ming-Han LIAO, Hsinchu (TW)

(21) Appl. No.: 19/335,110

(22) Filed: Sep. 22, 2025

Related U.S. Application Data
(60) Provisional application No. 63/790,670, filed on Apr. 17, 2025.

(51) Int. Cl. H10D 62/17; H10D 30/00; H10D 30/01; H10D 62/10; H10D 62/60

(52) U.S. Cl. CPC H10D 62/314; H10D 30/0191; H10D 30/502; H10D 62/60; H10D 62/121

(57) ABSTRACT

Embodiments of the present disclosure provide a semiconductor device including diffusion barrier layers formed on a semiconductor channel layer and methods of forming the same. The diffusion barrier layers formed on semiconductor channel layers mitigates diffusions from adjacent sacrificial channel layers, thereby, improving crystallinity of the semiconductor channel layers in the multi-channel devices.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2-7, 7A-7C, 8-14, 15A-15B, and 16, 16A-16C schematically illustrate various stages of manufacturing a semiconductor device according to embodiments of the present disclosure.

FIGS. 17A-17B schematically illustrate a stage of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of the present disclosure provide a semiconductor device including two or more stacked semiconductor channel layers, wherein at least one surface of the semiconductor channel layers includes a diffusion barrier layer. In some embodiments, the two or more stacked semiconductor channel layers may be epitaxially grown on a semiconductor substrate with sacrificial channel layers in between. In some embodiments, the diffusion barrier layer is formed between the semiconductor channel layer and the neighboring semiconductor sacrificial layer. In some embodiments, the semiconductor sacrificial layer may include a first semiconductor element, which is not included in the semiconductor channel layers or included in the semiconductor channel layers at a significantly different concentration. The presence of the first semiconductor element or the concentration differential of the first semiconductor element facilitates etch selectivity between the semiconductor channel layer and sacrificial channel layer, therefore, allowing the removal of the sacrificial channel layers during processing. However, the first semiconductor element may diffuse from the semiconductor sacrificial layer to the adjacent semiconductor channel layers, resulting in rough surfaces on the semiconductor channel layers. The diffusion barrier layer prevents the first semiconductor element from diffusing into the semiconductor channel layers, therefore, resulting sharp planar surfaces on the semiconductor channel layers. The diffusion barrier layer improves better gate control in the transistors, such as reducing subthreshold swing and DIBL (drain-induced barrier lowering). In some embodiments, the diffusion barrier layer may be an epitaxial grown layer and doped with a dopant to prevent diffusion across semiconductor layers. In some embodiments, the diffusion barrier layer may be an epitaxial grown layer doped an element to mitigate diffusion of the first semiconductor element. In some embodiments, the first semiconductor element is germanium, and the doped element is carbon. In some embodiments, the diffusion barrier film may include C, SiC, SiGeC, GeC, or the likes.

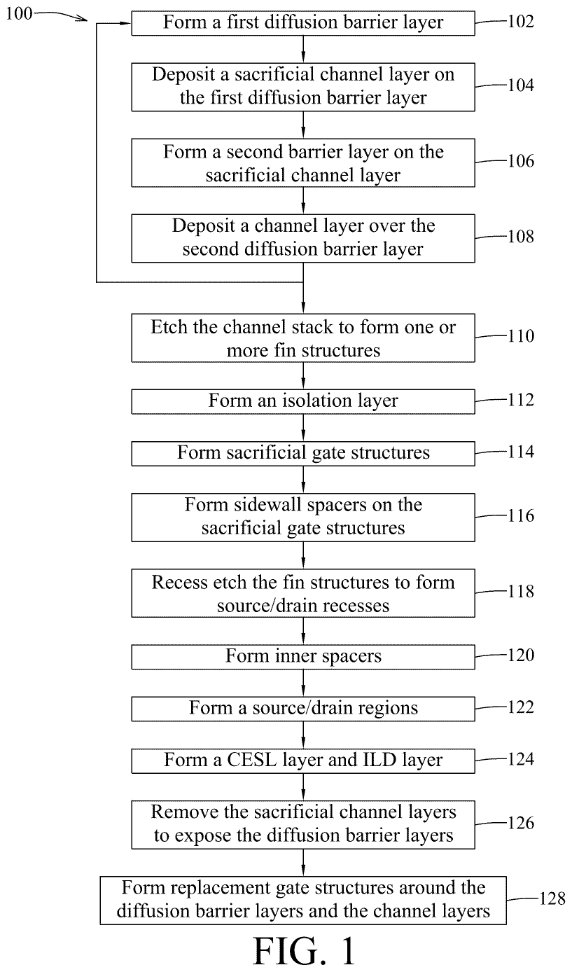

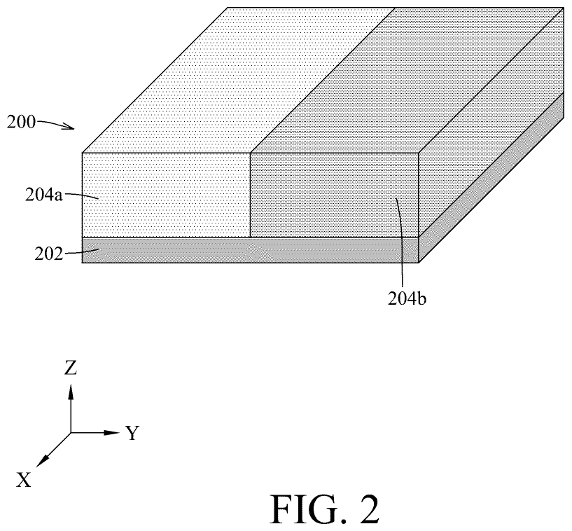

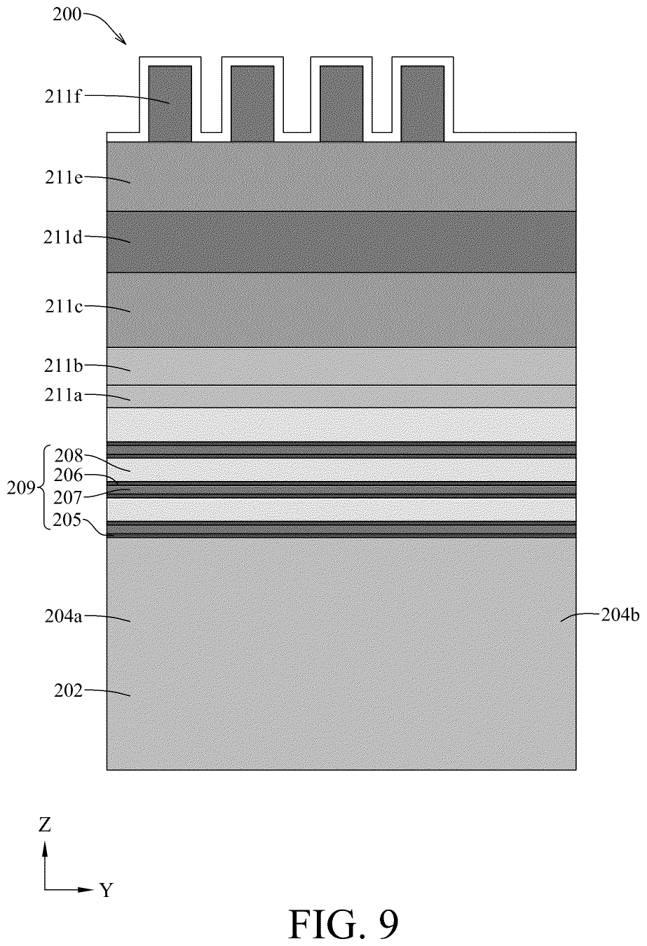

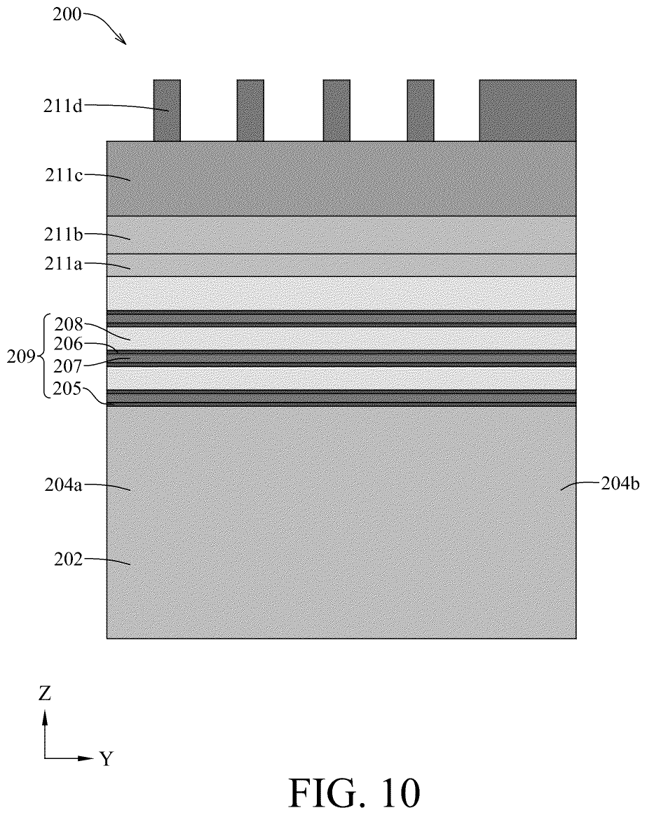

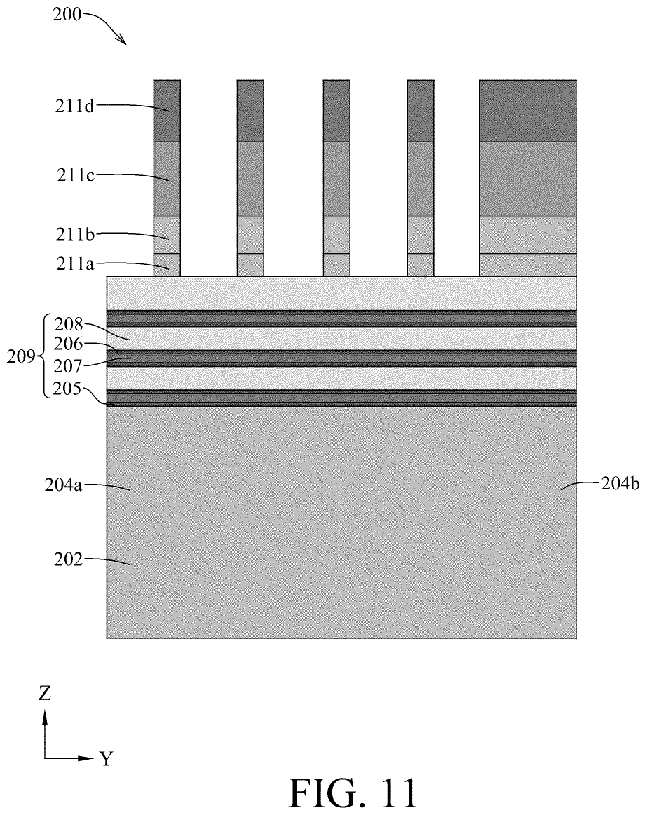

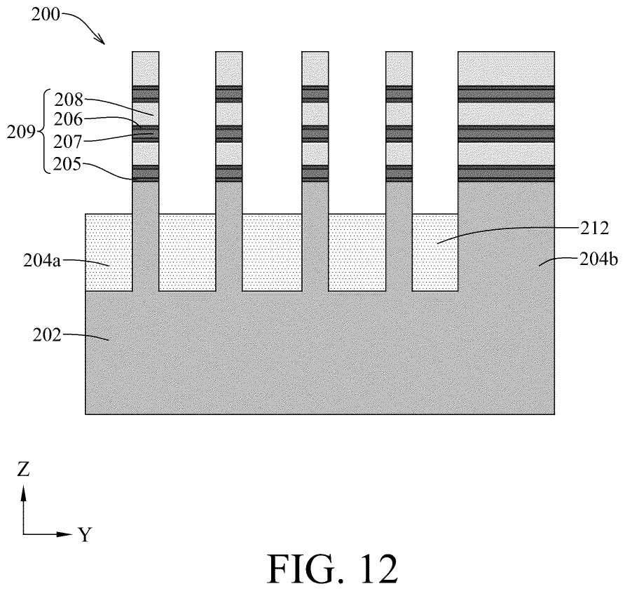

FIG. 1 is a flow chart of a method 100 for manufacturing of a semiconductor device 200 according to embodiments of the present disclosure. FIGS. 2-7, 7A-7B, 8-14, 15A-15B, 16, and 16A-16C schematically illustrate various stages of manufacturing an exemplary semiconductor device 200 according to embodiments of the present disclosure. Particularly, the semiconductor device 200 may be manufactured according to the method 100 of FIG. 1.

The semiconductor device 200 include GAA transistors formed from a stack of semiconductor layers. As shown in FIGS. 2-7 and operations 102, 104, 106, and 108, a stack 209 of semiconductor layers according to the present disclosure is formed over a substrate 202. FIGS. 2-7 are schematic perspective views of the semiconductor device 200 during various stages of fabrication according to embodiments of the present disclosure.

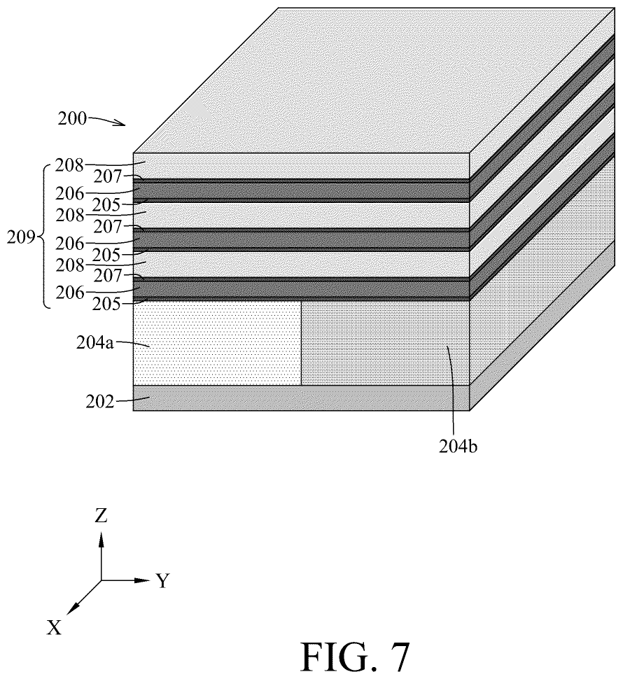

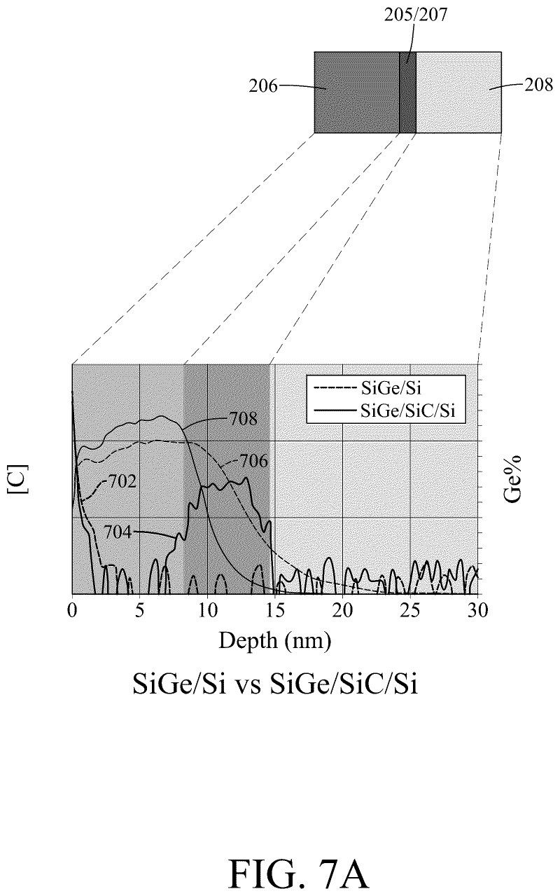

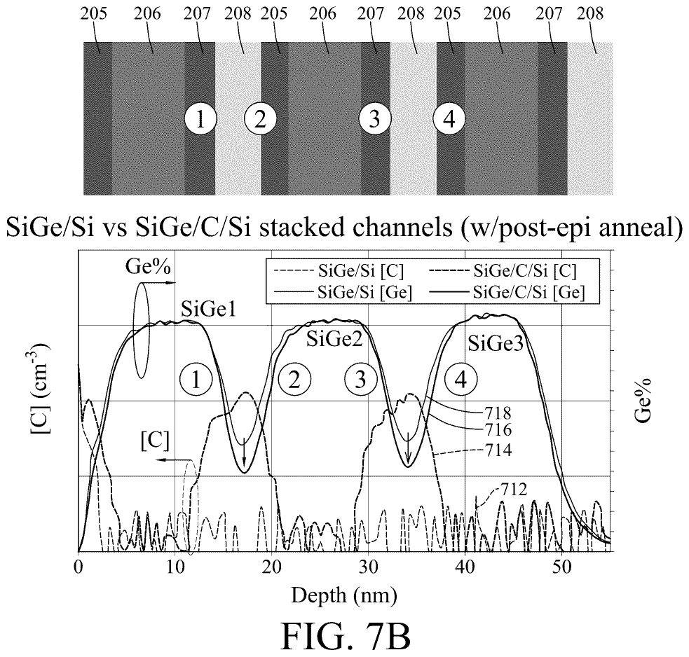

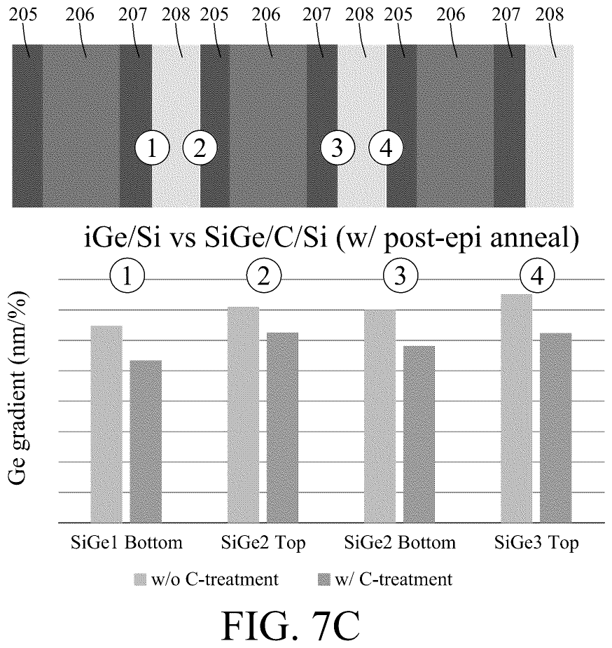

As shown in FIG. 7, the stack 209 includes two or more sacrificial channel layers 206 intervening with two or more semiconductor channel layers 208. The sacrificial channel layer 206 may be sandwiched between a first diffusion barrier layer 205 and a second diffusion barrier layer 207. The diffusion barrier layers 205, 207 are configured to prevent elements in the sacrificial channel layer 206, such as germanium, from diffusing into the adjacent semiconductor channel layers 208. The diffusion barrier layers 205, 207 may also be referred to as capping layers.

As shown in FIG. 2, the substrate 202 is provided to form the semiconductor device 200 thereon. The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. In FIG. 2, the substrate 202 includes a p-doped region or p-well 204a and an n-doped region or n-well 204b. One or more n-type devices, such as nFETs, are to be formed over and/or within p-well 204a. One or more p-type devices, such as pFETs, are to be formed over and/or within n-well 204b. FIG. 2 shows that the p-well 204a is in a doped local region of a doped substrate, which is not limiting. In other embodiments, the p-well 204a and the n-well 204b may be separated by one or more insulation bodies, e.g., STI.

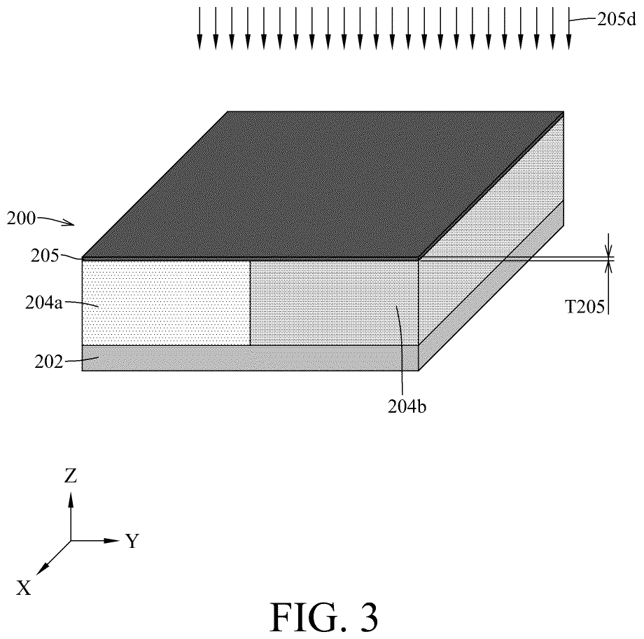

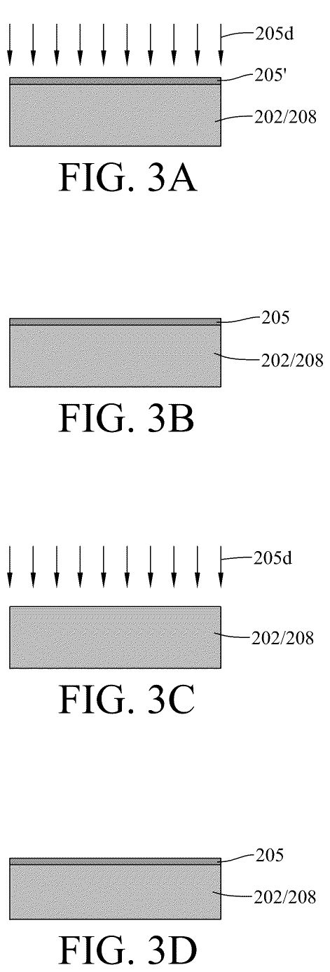

In operation 102, a first diffusion barrier layer 205 is formed over the substrate 202, as shown in FIG. 3. The first diffusion barrier layer 205 is intended to prevent diffusion from a subsequently formed sacrificial channel layer 206. The first diffusion barrier layer 205 may be formed by doping an epitaxially formed semiconductor layer.

In some embodiments, an epitaxial semiconductor layer 205′ may be first formed over the substrate 202 followed by a doping treatment 205d, as shown in FIGS. 3A-3B, which are partial sectional view of the semiconductor device 200. In some embodiments, the first diffusion barrier layer 205 may be configured to prevent a first semiconductor element, such as germanium, from diffusing into a semiconductor layer of a second semiconductor element, such as silicon. In some embodiments, the doping treatment 205d is configured to add a carbon to the first diffusion barrier layer 205, i.e., the first diffusion barrier layer 205 is a carbon doped epitaxial film.

In some embodiments, the diffusion barrier layer 205 may be formed by depositing the epitaxially grown film 205′ and then doping the epitaxially grown film 205′. For example, the epitaxial grown film 205′ may be an epitaxially grown carbon film, an epitaxially grown silicon film, an epitaxially grown silicon germanium film, or an epitaxially grown germanium film. The doping treatment may be performed to implant one or more element, for example, carbon, to the epitaxially grown film.

The doping treatment may be performed by an epitaxial process, implantation process, an atomic layer deposition process, or the like. In some embodiments, the doping treatment may be performed using process gases including SiH₄, SiH₂Cl₂, Si₂H₆, GeH₄, Ge₂H₆, SiH₃CH₃, CₓH_{y}, HCl, Cl₂, H₂, N₂, or a combination thereof. In some embodiments, the doping treatment is performed by an epitaxial process. The doping treatment may be performed under a pressure in a range between about 1 Torr and about 760 torr, a temperature in a range between about 300 °C and about 800 °C. The precursor gas flow may be in a range between about 1 sccm and about 1000 sccm. The purge gas and carrier gas may be flown in a gas flow ranging between about 1 SLM and about 50 SLM.

In other embodiments, the diffusion barrier layer 205 may be formed by performing a doping treatment directly on the substrate 202 or the semiconductor channel layer 208, as shown in FIGS. 3C-3D, which are partial sectional view of the semiconductor device 200. The doping treatment results in the first diffusion barrier layer 205 on a top portion of the substrate 202 or the semiconductor channel layer 208.

In some embodiments, the first diffusion barrier layer 205 may have a thickness T205 along the z-direction. In some embodiments, the thickness T205 is in a range between about 0.01 nm and about 10 nm, for example, between about 0.01 nm and about 0.1 nm, between about 0.1 nm and about 1.0 nm, and between about 1.0 nm and about 10 nm. If the thickness T205 of the first diffusion barrier layer 205 is greater than 10 nm, the electrical performance of the semiconductor device 200 may be adversely affected. If the thickness T205 of the first diffusion barrier layer 205 is less than 0.01 nm, the first diffusion barrier layer 205 may not be sufficient to prevent diffusion into the semiconductor channel layers 208. The thickness T205 may be selected according to the thickness of the semiconductor channel layers 208. For example, for thicker semiconductor channel layers 208, the thickness T205 may be thicker, and for thinner semiconductor channel layers 208, the thickness T205 may be thinner. In some embodiments, thickness of semiconductor channel layers 208 is in a range between about 0.1 num and about 10 nm. In some embodiments, a ratio of the thickness T205 over the thickness of the semiconductor channel layers 208 is in a range between about 0.001 and about 100. If the thickness ratio of the first diffusion barrier layer 205 over the semiconductor channel layer 208 is lower than 0.001, the first diffusion barrier layer 205 may not be thick enough to provide diffusion barrier to the semiconductor channel layer 208. If thickness ratio of the first diffusion barrier layer 205 over the semiconductor channel layer 208 is greater than 100, the electrical performance of the semiconductor device 200 may be adversely affected.

It has been observed that elements with atomic radius smaller than that of Ge and/or Si can be used to form diffusion barrier layer against Ge and/or Si or as dopants for implantation. In some embodiments, the first diffusion barrier layer 205 include one or more elements with atomic radius smaller than that of Ge and/or Si. In some embodiments, the diffusion barrier layer 205 may be an epitaxial grown film including one or more elements having atomic radius smaller than Ge and Si to prevent diffusion into or out of the semiconductor channel layer 208. In some embodiments, the first diffusion barrier layer 205 comprises carbon, boron, arsenic, silicon carbide, silicon boron, silicon arsenic, silicon doped with carbon, silicon doped with boron, silicon doped with arsenic, silicon germanium carbide, germanium carbide, or combinations thereof. Suitable elements with smaller atomic radius may include carbon, boron, arsenic, or combination thereof.

In some embodiments, the first diffusion barrier layer 205 may be an epitaxial grown film comprising carbon, silicon carbide (SiC), SiGeC, GeC, or the like. In some embodiments, the concentration of dopant, such as carbon, is in a range between about 1E19 cm−3 and about 1E22 cm−3, for example between about 1E19 cm−3 and about 1E20 cm−3, between about 1E20 cm−3 and about 1E21 cm−3, between about 1E21 cm−3 and about 1E22 cm−3. If the concentration of dopant is below 1E19 cm−3, the first diffusion barrier layer 205 may be provide enough barrier against diffusion. If the concentration of dopant is greater than 1E22 cm−3, the dopants in the first diffusion barrier film 205 may adversely affect the transistor performance without providing additional barrier function. In some embodiments, the atomic concentration of dopant, such as carbon, is in a range between about 0.02% and about 20%, for example between about 0.02% and about 0.2%, between about 0.2% and about 2%, and between about 2% and about 20%. If the atomic concentration of dopant is below 0.02%, the first diffusion barrier layer 205 may be provide enough barrier against diffusion. If the atomic concentration of dopant is greater than 20%, the dopants in the first diffusion barrier film 205 may adversely affect the transistor performance without providing additional barrier function. The doping concentration may be selected according to the thickness of the first barrier layer 205. For example, for a thinner diffusion barrier layer 205, the dopant concentration may be greater, and for a thicker diffusion barrier layer 205, the dopant concentration may be smaller.

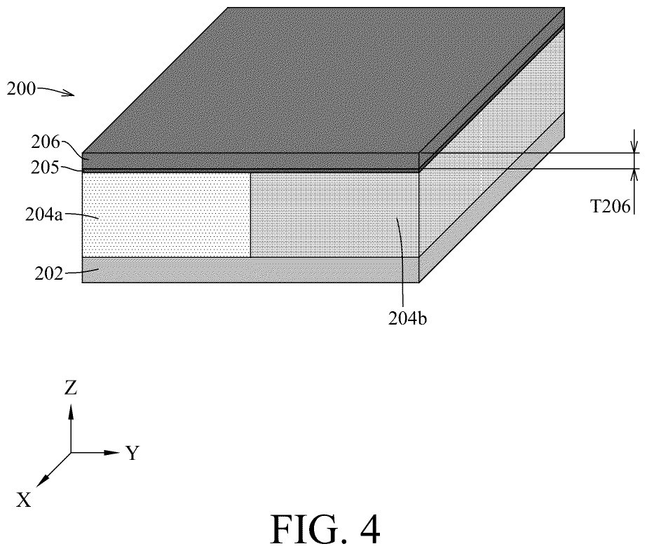

In operation 104, a sacrificial channel layer 206 is formed over the first diffusion barrier layer 205, as shown in FIG. 4. In some embodiments, the sacrificial channel layer 206 may include silicon germanium (SiGe). The sacrificial channel layer 206 may be a SiGe layer including more than 25% Ge in molar ratio. For example, the sacrificial channel layer 206 may be a SiGe layer including Ge in a molar ration in a range between 25% and 50%. The sacrificial channel layer 206 may be formed by a molecular beam epitaxy (MBE) process, a metalorganic chemical vapor deposition (MOCVD) process, and/or other suitable epitaxial growth processes. The sacrificial channel layer 206 has a thickness T206 along the z-direction. In some embodiments, the thickness T206 is in a range between about 5 nm and about 50 nm.

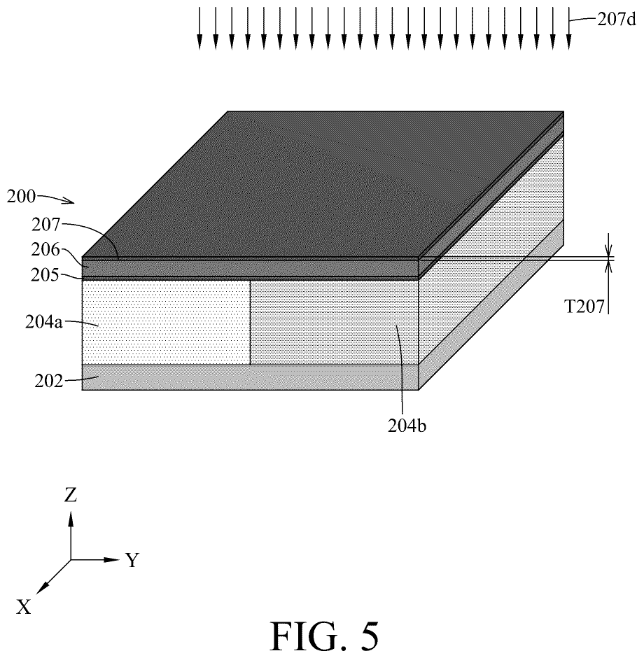

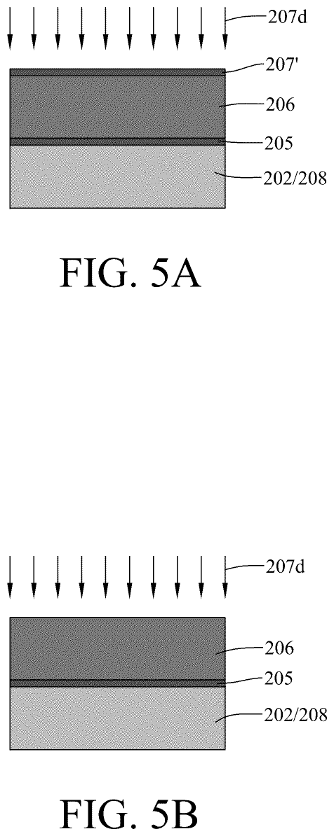

In operation 106, a second diffusion barrier layer 207 is formed over the sacrificial channel layer 206, as shown in FIG. 5. The second diffusion barrier layer 207 is intended to prevent diffusion from the sacrificial channel layer 206 to the subsequently formed semiconductor channel layer 208.

In some embodiments, the second diffusion barrier layer 207 may be formed by doping an epitaxially formed semiconductor layer. In some embodiments, an epitaxial semiconductor layer 207′ may be first formed over the sacrificial channel layer 206 followed by a doping treatment 207d, as shown in FIG. 5A, which is a partial cross sectional view of the semiconductor device 200. In some embodiments, the second diffusion barrier layer 207 may be configured to prevent an element in the sacrificial channel layer 206, such as germanium, from diffusing into the subsequently formed semiconductor channel layer 208. In some embodiments, the doping treatment 207d is configured to add a carbon to the second diffusion barrier layer 207, i.e., the second diffusion barrier layer 207 is a carbon doped epitaxial film. The epitaxial grown film 207′ may be an epitaxially grown carbon film, an epitaxially grown silicon film, an epitaxially grown silicon germanium film, or an epitaxially grown germanium film. The doping treatment may be performed to implant one or more element, for example, carbon, to the epitaxially grown film 207′.

The doping treatment may be performed by an epitaxial process, implantation process, an atomic layer deposition process, or the like. In some embodiments, the doping treatment may be performed using process gases including SiH₄, SiH₂Cl₂, Si₂H₆, GeH₄, Ge₂H₆, SiH₃CH₃, CₓH_{y}, HCl, Cl₂, H₂, N₂, or a combination thereof. In some embodiments, the doping treatment is performed by an epitaxial process. The doping treatment may be performed under a pressure in a range between about 1 torr and about 760 torr, a temperature in a range between about 300 °C and about 800 °C. The precursor gas flow may be in a range between about 1 sccm and about 1000 sccm. The purge gas and carrier gas may be flown in a gas flow ranging between about 1 SLM and about 50 SLM.

In other embodiments, the second diffusion barrier layer 207 may be formed by performing a doping treatment directly on the sacrificial channel layer 206, as shown in FIG. 5B, which is a partial cross sectional view of the semiconductor device 200. The doping treatment results in the second diffusion barrier layer 207 from a top portion of the sacrificial channel layer 206.

In some embodiments, the second diffusion barrier layer 207 may have a thickness T207 along the z-direction. In some embodiments, the thickness T207 is in a range between about 0.01 nm and about 10 nm, for example, between about 0.01 nm and about 0.1 nm, between about 0.1 nm and about 1.0 nm, and between about 1.0 nm and about 10 nm. If the thickness T207 of the first diffusion barrier layer 207 is greater than 10 nm, the electrical performance of the semiconductor device 200 may be adversely affected. If the thickness T207 of the first diffusion barrier layer 207 is less than 0.01 nm, the first diffusion barrier layer 207 may not be sufficient to prevent diffusion into the semiconductor channel layers 208. The thickness T207 may be selected according to the thickness of the semiconductor channel layers 208. For example, for thicker semiconductor channel layers 208, the thickness T207 may be thicker, and for thinner semiconductor channel layers 208, the thickness T207 may be thinner. In some embodiments, a ratio of the thickness T207 over the thickness of the semiconductor channel layers 208 is in a range between about 0.001 and about 100. If the thickness ratio of the first diffusion barrier layer 207 over the semiconductor channel layer 208 is lower than 0.001, the first diffusion barrier layer 207 may not be thick enough to provide diffusion barrier to the semiconductor channel layer 208. If thickness ratio of the first diffusion barrier layer 207 over the semiconductor channel layer 208 is greater than 100, the electrical performance of the semiconductor device 200 may be adversely affected.

In some embodiments, the second diffusion barrier layer 207 may be an epitaxial grown film comprising carbon, silicon carbide (SiC), SiGeC, GeC, or the like. In some embodiments, the concentration of dopant, such as carbon, in a range between about 1E19 cm−3 1E22 cm−3, for example between about between about 1E19 cm−3 and about 1E20 cm−3, between about 1E20 cm−3 and about 1E21 cm−3, between about 1E21 cm−3 and about 1E22 cm−3. In some embodiments, the atomic concentration of dopant, such as carbon, is in a range between about 0.02% and about 20%, for example between about 0.02% and about 0.2%, between about 0.2% and about 2%, and between about 2% and about 20%. The doping concentration may be selected according to the thickness of the second diffusion barrier layer 207. For example, for a thinner second diffusion barrier layer 207, the dopant concentration may be greater, and for a thicker second diffusion barrier layer 207, the dopant concentration may be smaller.

The first diffusion barrier layer 205 and the second diffusion barrier layer 207 may have the same composition or the different composition. In some embodiments, the first diffusion barrier layer 205 may be formed from treating a top portion of the substrate 202/semiconductor channel layer 208 with carbon, therefore, including SiC, while the second diffusion barrier layer 207 may be formed from treating a top portion of the sacrificial channel layer 206 with carbon, therefore, including SiGeC. In other embodiments, the first diffusion barrier layer 205 and the second diffusion barrier layer 207 are both formed from doping an epitaxial silicon layer, and including SiC.

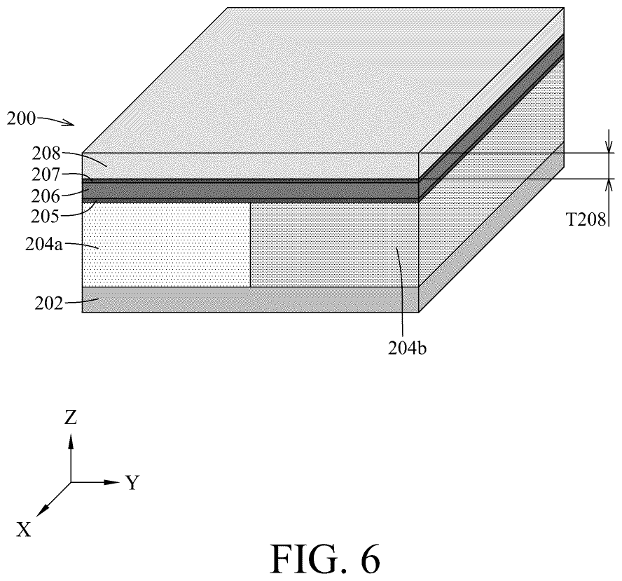

In operation 108, a semiconductor channel layer 208 is formed over the second diffusion barrier layer 207, as shown in FIG. 6. In some embodiments, the semiconductor channel layer 208 may include silicon, Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof. In some embodiments, the semiconductor channel layer 208 may include undoped silicon. In later fabrication stages, portions of the semiconductor channel layer 208 form nanosheet channels in a multi-gate device. The semiconductor channel layer 208 may be formed by a molecular beam epitaxy (MBE) process, a metalorganic chemical vapor deposition (MOCVD) process, and/or other suitable epitaxial growth processes. The semiconductor channel layer 208 has a thickness T208 along the z-direction. In some embodiments, the thickness T208 is in a range between about 5 nm and about 50 nm.

As shown in FIG. 6, after operations 102, 104, 106, and 108, a pair of sacrificial channel layer 206 and semiconductor channel layer 208, with the sacrificial channel layer 206 sandwiched between the first diffusion barrier layer 205 and the second diffusion barrier layer 207. Operations 102, 104, 106, 108 may be repeated to form a stack 209 with layers 205, 206, 207, 208 for additional pairs of sacrificial channel layer 206 and semiconductor channel layer 208. As shown in FIG. 7, three sacrificial channel layers 206 and three semiconductor channel layers 208 are alternately arranged as an example. More or less pairs of sacrificial channel layer 206 and semiconductor channel layer 208 may be included depending on the desired number of channels in the semiconductor device to be formed. In some embodiments, the number of pairs of sacrificial channel layer 206 and semiconductor channel layer 208 may be between 1 and 10.

In some embodiments, the diffusion barrier layers 205, 207 in each pair of sacrificial channel layer 206 and semiconductor channel layer 208 have substantially the same thickness T205, T207. In other embodiments, the diffusion barrier layers 205, 207 in different pairs of sacrificial channel layer 206 and semiconductor channel layer 208 have substantially different thicknesses according to device design.

In some embodiments, while the doping treatment is performed by an epitaxial process, operations 102, 104, 106, and 108 may be performed sequentially in the same epitaxial processing chamber by varying processing gases to obtain epitaxial films of different compositions. Accordingly, the first diffusion barrier layer 205, the sacrificial channel layer 206, the second diffusion barrier layer 207, and the semiconductor channel layer 208 are sequentially formed in the same epitaxial processing chamber.

As discussed above, the first and second diffusion barrier layers 205 and 207 prevent elements in the sacrificial channel layer 206, such as germanium, from diffusing into the semiconductor channel layer 208, thus maintaining crystallinity between at the interface between the sacrificial channel layer 206 and the semiconductor channel layer 208.

FIG. 7A schematically illustrates the diffusion blocking effect of the diffusion barrier layer 205/207. FIG. 7A illustrates profiles of germanium concentration along a stack of layers including a sacrificial channel layer 206, a diffusion barrier layer 207, and a semiconductor channel layer 208. The sacrificial channel layer 206 includes SiGe, the diffusion barrier layer 207 includes silicon doped with carbon, and the semiconductor channel layer 208 includes silicon. Curve 704 and curve 708 indicate carbon concentration and germanium concentration along the depth of stack the sacrificial channel layer 206, the diffusion barrier layer 207, and the semiconductor channel layer 208 respectively. As shown by curves 708 and 704, the germanium concentration drops sharply through the diffusion barrier layer 207 which has been doped with carbon, and the germanium concentration is insignificant. Curve 702 and curve 706 indicate carbon concentration and germanium concentration along a stack of a sacrificial channel layer 206 and the semiconductor channel layer 208 without the diffusion barrier layer 207. As shown by curves 706 and 702, without the diffusion barrier layer 207, germanium in the SiGe layer diffuses significantly into the silicon layer. Comparison of curve 708 and curve 706 shows that the carbon doped diffusion barrier layer 207 effectively prevents diffusion of germanium from a SiGe layer to a Si layer.

FIG. 7B schematically illustrates germanium and carbon distribution along the stack 209 of FIG. 7. FIG. 7B illustrates profiles of germanium concentration along the stack 209 including the first diffusion barrier layers 205, the sacrificial channel layers 206, the diffusion barrier layers 207, and the semiconductor channel layers 208 sequentially arranged. The sacrificial channel layer 206 includes SiGe, the diffusion barrier layers 205, 207 include carbon, and the semiconductor channel layer 208 includes silicon. Curve 714 and curve 716 indicate carbon concentration and germanium concentration along the depth of the stack 209 respectively. As shown by curves 716 and 714, the germanium concentration drops sharply through the diffusion barrier layers 205/207 in the semiconductor channel layers 208. Curve 712 and curve 718 indicate carbon concentration and germanium concentration along a stack of a sacrificial channel layer 206 and the semiconductor channel layer 208 without the diffusion barrier layer 205/207. As shown by curves 718 and 712, without the diffusion barrier layers 205/207, germanium in the sacrificial channel layers 206 diffuses significantly into the semiconductor channel layers 208.

FIG. 7C schematically illustrates germanium gradient at across top surfaces and bottom surfaces of semiconductor channel layers 208 in the stack 209 of FIG. 7. FIG. 7C illustrates germanium gradients at interfaces 1, 2, 3, 4 as marked in the stack 209. Gray columns are germanium gradients at interfaces 1, 2, 3, 4 without carbon doping. Gray columns are germanium gradients at interfaces 1, 2, 3, 4 with carbon doping. As shown in FIG. 7C, by introducing carbon doping, germanium gradients at interfaces between the SiGe and Si layers are reduced, indicating reduced diffusion of Ge across the interfaces.

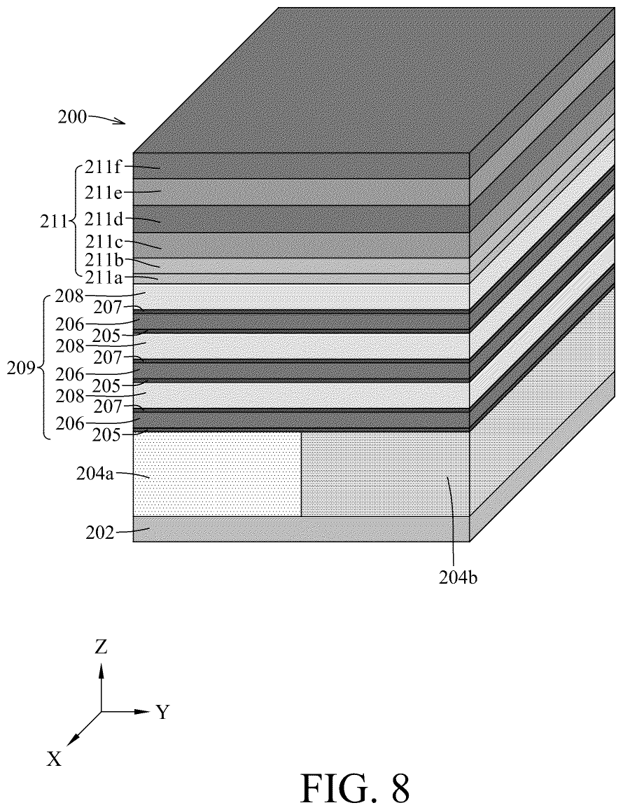

At operation 110, fin structures 210 are formed over the substrate 202 using one or more etching processes, as shown in FIGS. 8, 9, 10, 11, and 12. As shown in FIG. 8, a masking stack 211 is formed over the stack 209 in accordance with some embodiments. As an example, the masking stack 211 may comprise a first dielectric layer 211a, a second dielectric layer 211b, a third dielectric layer 211c, a polysilicon layer 211d, an advanced patterning film (APF) 211e, and a bottom anti-reflective coating (BARC) 211f. Generally, the first dielectric layer 211a, the second dielectric layer 211b, and third dielectric layer 211c act as a hard mask while the polysilicon layer 211d, the APF 211e and the BARC 211f in combination will be used to pattern the hard mask and for critical dimension control in order to obtain and control the desired dimensions of the patterning of the hard mask, e.g., the first dielectric layer 211a, the second dielectric layer 211b, and third dielectric layer 211c. In some embodiments the first dielectric layer 211a, the second dielectric layer 211b, and the third dielectric layer 211c comprise an oxide-nitride-oxide (ONO) layer, wherein the first dielectric layer 211a may be an oxide, e.g., silicon oxide, the second dielectric layer 211b is a nitride, e.g., silicon nitride, and the third dielectric layer 211c may be an oxide, e.g., silicon oxide.

The masking stack 211 may be sequentially patterned and eventually forming fin structures 210. Each fin structure 210 may include a stack portion including layers 205, 206, 207, 208 and a well portion 204.

In operation 112, an isolation layer 212 is filled in trenches between the fin structures 210 and then etched back to below the stack portion of the fin structures 210. The isolation layer 212 may be formed by a high-density plasma chemical vapor deposition (HDP-CVD), a flowable CVD (FCVD), or other suitable deposition process. In some embodiments, the isolation layer 212 may include silicon oxide, silicon nitride, silicon oxynitride, fluorine-doped silicate glass (FSG), a low-k dielectric, combinations thereof.

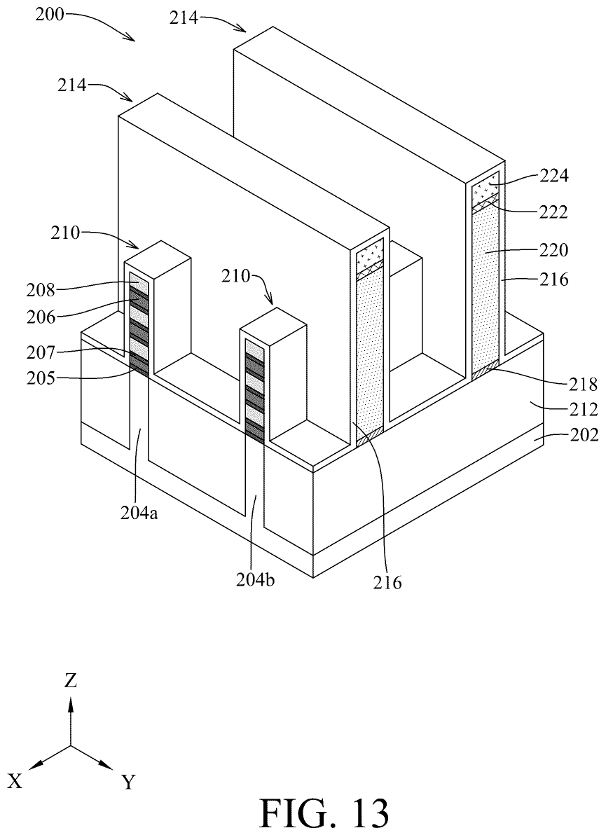

In operation 114, sacrificial gate structures 214 are formed over the isolation layer 212 and around the exposed portions of the fin structures 210, as shown in FIG. 13. The sacrificial gate structures 214 are formed over portions of the fin structures 210 which are to be channel regions. Trenches are formed between neighboring sacrificial gate structures 214. The sacrificial gate structures 214 are substantially perpendicular to the fin structures 210.

The sacrificial gate dielectric layer 218 may be formed conformally over the fin structures 210, and the isolation layer 212. In some embodiments, the sacrificial gate dielectric layer 218 may be deposited by a CVD process, a sub-atmospheric CVD (SACVD) process, a FCVD process, an ALD process, a PVD process, or other suitable process. The sacrificial gate dielectric layer 218 may include one or more layers of dielectric material, such as SiO₂, SiN, a high-k dielectric material, and/or other suitable dielectric material.

The sacrificial gate electrode layer 220 may be blanket deposited on the sacrificial gate dielectric layer 218. The sacrificial gate electrode layer 220 includes silicon such as polycrystalline silicon or amorphous silicon. The thickness of the sacrificial gate electrode layer is in a range between about 42 nm and about 200 nm. In some embodiments, the sacrificial gate electrode layer 220 is subjected to a planarization operation. The sacrificial gate electrode layer 220 may be deposited using CVD, including LPCVD and PECVD, PVD, ALD, or other suitable process.

Subsequently, the pad layer 222 and the mask layer 224 are formed over the sacrificial gate electrode layer 220. The pad layer 222 may include silicon nitride. The mask layer 224 may include silicon oxide. Next, a processing sequence including patterning and etching is performed on the mask layer 224, the pad layer 222, the sacrificial gate electrode layer 220 and the sacrificial gate dielectric layer 218 to form the sacrificial gate structures 214. Portions of the sacrificial gate electrode layer 220 and the sacrificial gate dielectric layer 218 are sequentially removed using patterns formed in the mask layer 224 to form the sacrificial gate structures 214.

In operation 116, gate sidewall spacer layer 216 may be deposited over the semiconductor device 200 by a blanket deposition of one or more insulating material, as shown in FIG. 13. The gate sidewall spacer layer 216 may include two or more layers of dielectric materials. In some embodiments, the gate sidewall spacer layer 216 may include one or more insulation material. The gate sidewall spacer layer 216 may include a silicon nitride-based material, such as SiN, SiON, SiOCN or SiCN and combinations thereof.

In operation 118, the fin structures 210 not covered by the sacrificial gate structures 214 are first etched to expose well portions of each fin structures 210 to form source/drain recesses. In some embodiments, suitable dry etching and/or wet etching may be used to etch back the layers 205, 206, 207 208, together or separately. A portion of the fin sidewall spacers 216 may remain after the fin structures 210 are recessed. A height of the remaining fin sidewall spacers 216 may be used to control the shape of the subsequently formed epitaxial source/drain regions.

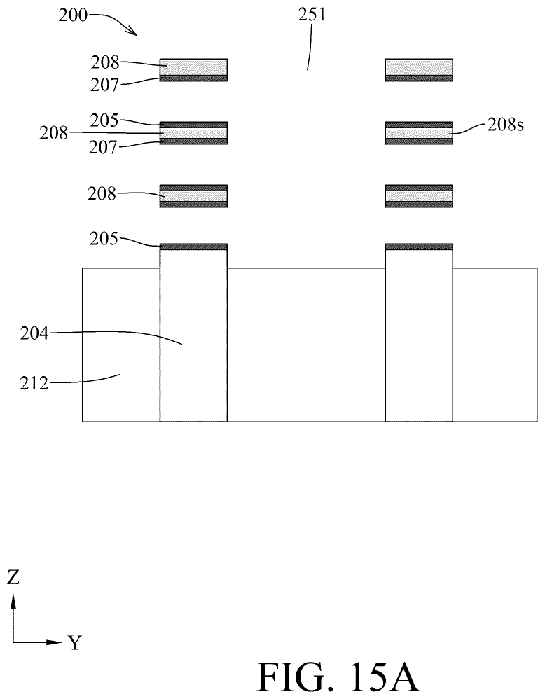

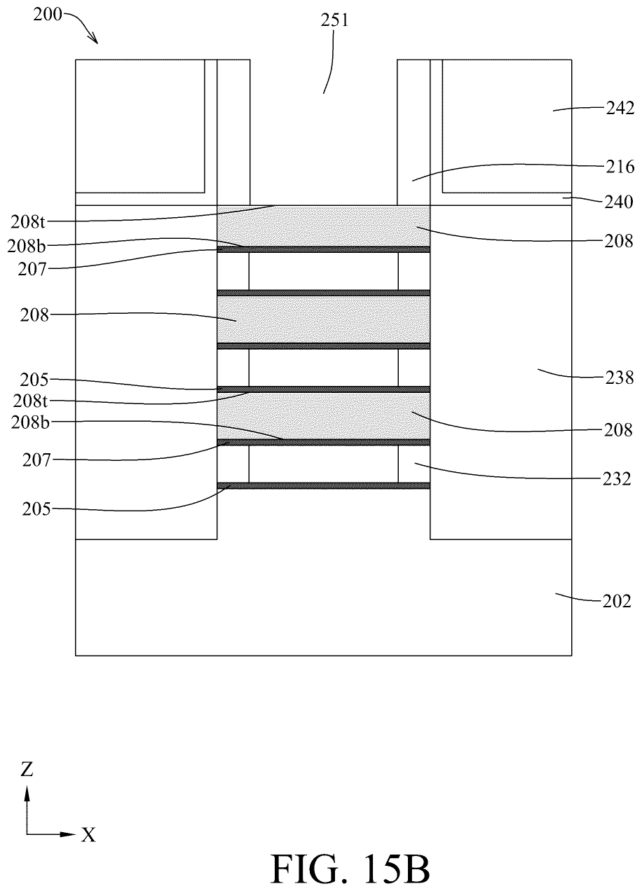

In operation 120, after recess etch of the fin structures 210, inner spacers 232, shown in FIG. 15B, are formed through the source/drain recesses 234. To form the inner spacers 232, the sacrificial channel layers 206 under the gate sidewall spacers 216 are selectively etched from the semiconductor layers 208 and the diffusion barrier layers 205, 207 along the horizontal direction, or x-direction, to form spacer cavities. In some embodiments, the sacrificial channel layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. After forming the spacer cavities, the inner spacers 232 are formed in the spacer cavities by conformally deposit and then partially remove an insulating layer. The insulating layer can be formed by ALD or any other suitable method. The subsequent etch process removes most of the insulating layer except inside the cavities, resulting in the inner spacers 232.

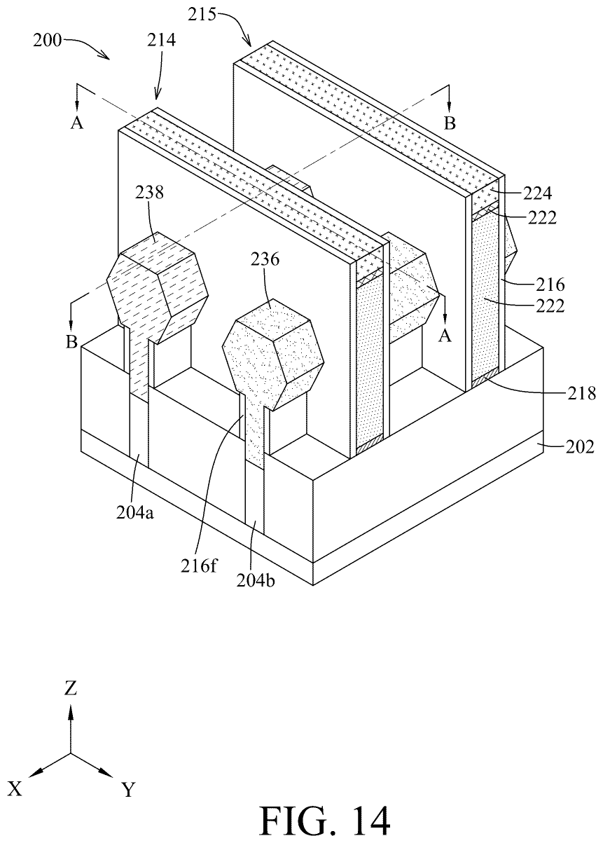

In operation 122, source/drain regions 236, 238 are formed, as shown in FIG. 14, which is a schematic perspective view of the semiconductor device 200. In some embodiments, the epitaxial source/drain regions 236. 238 may be for different types of devices and may be formed separately using patterning processes. In some embodiments, the epitaxial source/drain regions 236 for N-type devices are formed from exposed surfaces of the fin structure 210b. The epitaxial source/drain regions 236 for n-type devices may include one or more layers of Si, SiP, SiC and SiCP. The epitaxial source/drain regions 236 also include N-type dopants, such as phosphorus (P), arsenic (As), etc. In some embodiments, the epitaxial source/drain regions 236 may be a Si layer includes phosphorus (P) dopants.

The epitaxial source/drain regions 238 may be for P-type devices. The epitaxial source/drain regions 238 may be formed by any suitable method, such as by CVD, CVD epitaxy, molecular beam epitaxy (MBE), or any suitable deposition technique. In some embodiments, the epitaxial source/drain regions 238. The epitaxial source/drain regions 238 for the p-type devices may include one or more layers of Si, SiGe, Ge with p-type dopants, such as boron (B), for a p-type device, such as pFET. In some embodiments, the epitaxial source/drain regions 238 may be SiGe material including boron as dopant. The sequence of the formation of epitaxial source/drain for NMOS and PMOS are exchangeable, subject to the requirement for the process requirement. The shape of epitaxial source/drain regions may be different for NMOS and PMOS, subject to the design of film scheme.

In operation 124, a contact etch stop layer (CESL) 240 and an interlayer dielectric (ILD) layer 242 are conformally formed over the semiconductor device 200, as shown in FIG. 15B, which is a cross sectional view of the semiconductor device 200 along B-B line on FIG. 14. The CESL 240 is formed over exposed surfaces of the semiconductor device 200. The CESL 240 is formed on the epitaxial source/drain regions 236, 238 the gate sidewall spacers 216, the fin sidewall spacers 216, and the isolation layer 212. The CESL 240 may include Si₃N₄, SiON, SiCN or any other suitable material, and may be formed by CVD, PVD, or ALD.

The ILD layer 242 is formed over the contact etch stop layer 240. The materials for the ILD layer 242 include compounds comprising Si, O, C, and/or H, such as silicon oxide, SiCOH and SiOC. Organic materials, such as polymers, may be used for the ILD layer 242. In some embodiments, the ILD layer 242 may be formed by flowable CVD (FCV). The ILD layer 242 and the CESL layer 240 protect the epitaxial source/drain regions 236, 238 during the removal of the sacrificial gate structures 214. In some embodiments, after depositing the ILD layer 242, a planarization process may be performed to expose the sacrificial gate structures 214.

In operation 126, the sacrificial gate structures 214 and the sacrificial channel layers 206 are removed to form gate cavities 251 as shown in FIGS. 15A and 15B, which are cross sectional views of the semiconductor device 200 along A-A line and B-B line on FIG. 14 respectively. The sacrificial gate electrode layer 220 and sacrificial gate dielectric layer 216 are first removed to expose the fin structures 210 covered by the sacrificial gate structure 214. The sacrificial gate electrode layer 220 can be removed using plasma dry etching and/or wet etching. After removal of the sacrificial gate electrode layer 220, the sacrificial gate dielectric layer 218 is exposed. An etch process may be performed to selectively remove the sacrificial gate dielectric layer 218 exposing the first diffusion barrier layers 205, the sacrificial channel layers 206, the second diffusion barrier layers 207, and the semiconductor channel layers 208.

The sacrificial channel layers 206 are partially removed to expose the first diffusion barrier layers 205, the second diffusion barrier layers 207, and the semiconductor channel layers 208, as shown in FIGS. 15A-15B. A suitable etching method may be used to selectively etch the sacrificial channel layers 206 while the first diffusion barrier layers 205, the second diffusion barrier layers 207, and the semiconductor channel layers 208 are substantially intact. The sacrificial channel layers 206 can be selectively etched using a suitable wet etchant or a dry etching process. In some embodiments, a dry etching process may be performed etching gases including fluorocarbon gas, such as CF₄, C₂F₆, C₃F₈, CHF₃, or CH₂F₂, to selectively remove the sacrificial channel layers 206.

Because the diffusion barrier layers 205, 207 prevent diffusion from the sacrificial channel layers 206 to the adjacent semiconductor channel layers 208, thus, substantially preserving etch selectivity between the sacrificial channel layers 206 and the semiconductor channel layers 208.

After operation 126, the semiconductor channel layers 208 remain covered by the first diffusion barrier layer 205 and/or the second diffusion barrier layer 207. Top surfaces 208t and bottom surfaces 208b of the semiconductor channel layers 208 are substantially planar. Particularly, a bottom surface 208b of the topmost semiconductor channel layer 208 is covered by a second diffusion barrier layer 207 while a top surface 208t of the topmost semiconductor channel layer 208 is exposed. The semiconductor channel layers 208 under the topmost semiconductor channel layer 208 have a first diffusion barrier layer 205 covering a top surface 208t and a second diffusion barrier layer 207 covering a bottom surface 208b. Side surfaces 208s are exposed to the gate cavity 251. In some embodiments, the first and the second diffusion barrier layers 205, 207 may be at least partially removed in operation 126 to improve electrical properties of the semiconductor device 200. In some embodiments, the first and the second diffusion barrier layers 205, 207 may be entirely removed in operation 126. However, residues of the dopant in the diffusion barrier layers 205.207, such as carbon residue, may be detected in the semiconductor channel layers 208.

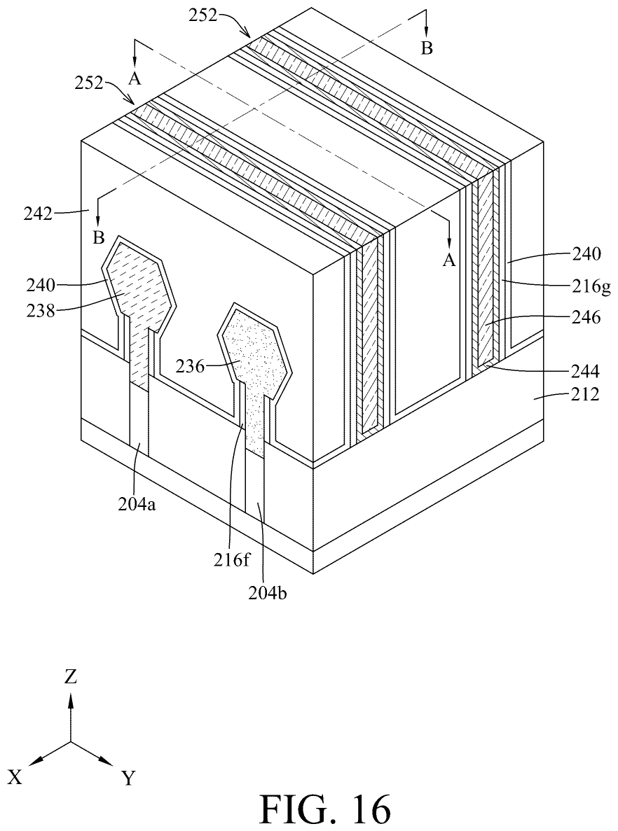

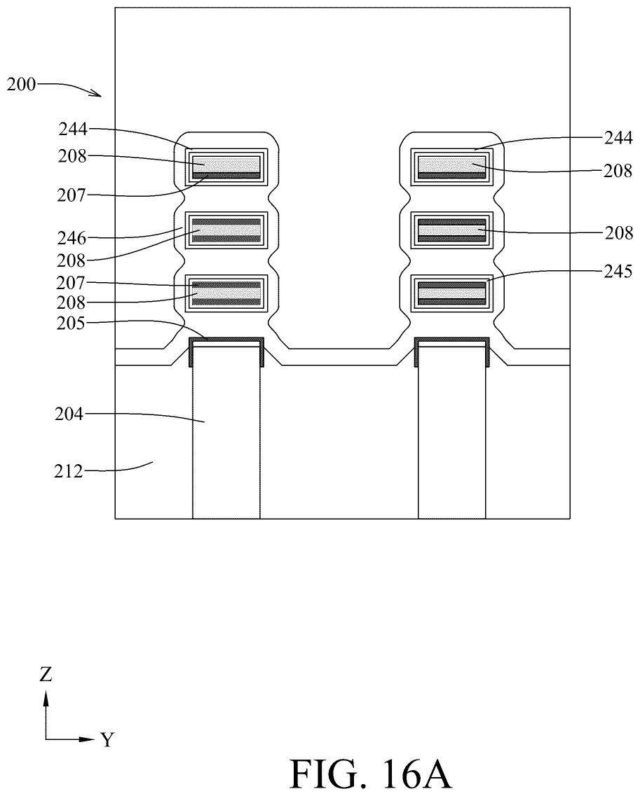

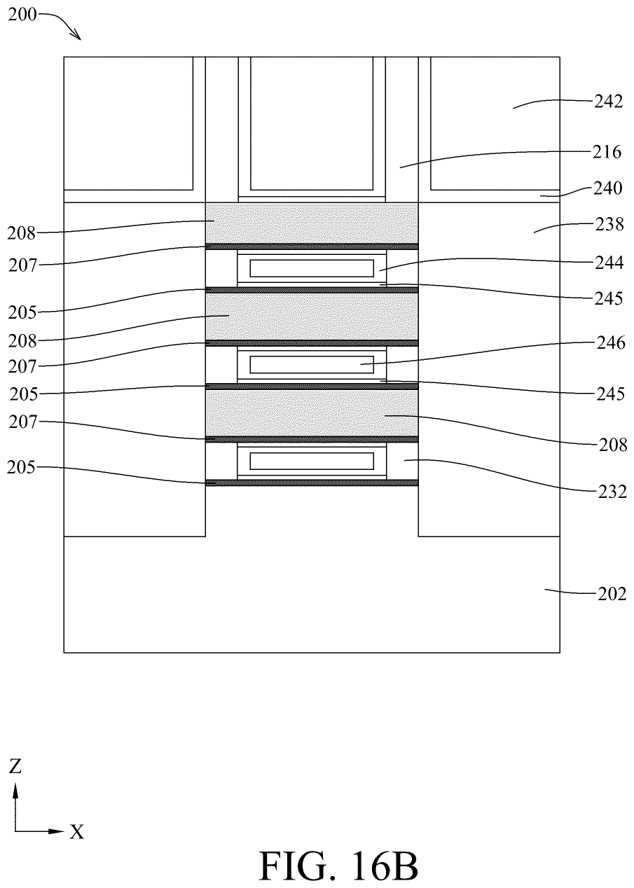

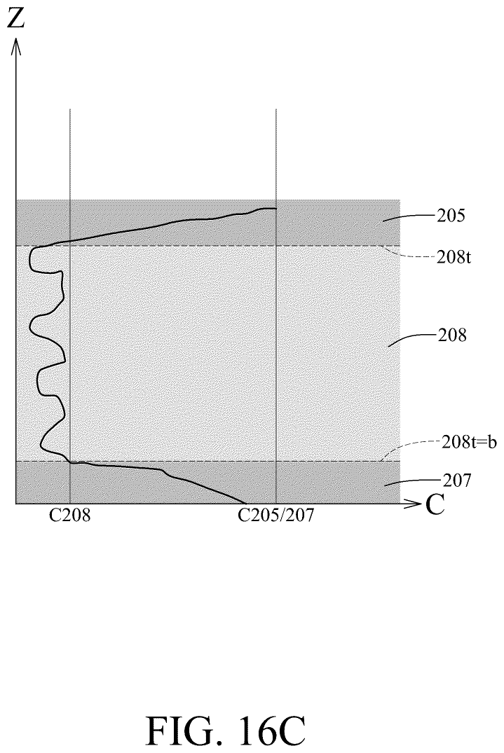

In operation 128, replacement gate structures 252 are formed around the semiconductor channel layers 208 as shown in FIGS. 16, 16A and 16B. The replacement gate structures 252 include a gate dielectric layer 244 and a gate electrode layer 246. The gate dielectric layer 244 is formed on exposed surfaces in the gate cavities. As shown in FIGS. 16A and 16B, the gate dielectric layer 244 are formed around the semiconductor channel layers 208. In some embodiments, the first diffusion barrier layer 205 is disposed between the semiconductor channel layer 208 and the gate dielectric layer 244, the second diffusion barrier layer 207 is disposed between the semiconductor channel layer 208 and the gate dielectric layer 244. On the side surfaces 208s of the semiconductor channel layers 208, the gate dielectric layer 244 is disposed on the semiconductor channel layer 208 without any barrier layers.

In some embodiments, an interfacial layer 245 is formed along exposed surfaces of the semiconductor channel layers 208, the first diffusion barriers 205, and the second diffusion barriers 207. The gate dielectric layer 244 is formed over the interfacial layer 245. The interfacial layer 245 helps buffer a subsequently formed high-k dielectric layer from the underlying semiconductor material. In some embodiments, the interfacial layer 245 is a chemical silicon oxide, which may be formed of chemical reactions. For example, a chemical oxide may be formed using deionized water and ozone (DIO₃), NH₄OH+H₂O₂+H₂O (APM), or other methods. In some embodiments, a different material or processes may be used to form the interfacial layer 245. In some embodiments, the interfacial layer 235 may have a thickness of about 3 Å to about 7 Å.

The gate dielectric layer 244 may have different composition and dimensions for N-type devices and P-type devices and are formed separately using patterned mask layers and different deposition recipes. The gate dielectric layer 244 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. The gate dielectric layer 244 may be formed by CVD, ALD or any suitable method.

The gate electrode layer 246 is formed on the gate dielectric layer 244 to fill the gate cavities. The gate electrode layer 246 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 246 may be formed by CVD, ALD, electro-plating, or other suitable method. The gate electrode layer 246 may have different composition and dimensions for N-type devices and P-type devices and are formed separately using patterned mask layers and different deposition recipes. In some embodiments, the gate electrode layer 246 for N-type devices may include TiAl. The gate electrode layer 246 for P-type devices may include TiN and TiAl.

As shown in FIGS. 16A-16B, the inner spacers 232 are in contact with the first diffusion barrier layer 205 and the second diffusion barrier layer 207. The first diffusion barrier layer 205 and the second diffusion barrier layer 207 are in contact with the source/drain regions 236/238 at end portions.

As shown in FIGS. 16A-16B, the first diffusion barrier layer 205 and the second diffusion barrier layer 207 remain in the semiconductor device 200, cladding on the semiconductor channel layer 208. The first and second diffusion barrier layers 205, 207 may be defected through dopant concentration. FIG. 16C is a schematic dopant profile along the z-direction across a semiconductor channel layer 208 according to embodiments of the present disclosure. As shown in FIG. 16, the dopant (carbon) concentration has an outer peak C205/207 near a top surface 208t and a bottom surface 208b, and an inner peak C208 near a middle portion. In some embodiments, a ratio of the outer peak C205/207 over the inner peak C208 is in a range between about 5 and about 50.0.

The diffusion barrier layers according to the present disclosure may include a single layer, as shown in the embodiments above. In some embodiments, the diffusion barrier layers, such as the diffusion barrier layers 205, 207, may include two or more doped layers. The two or more doped layers may include different epitaxial materials, different doping profiles, different dopants, or combinations thereof.

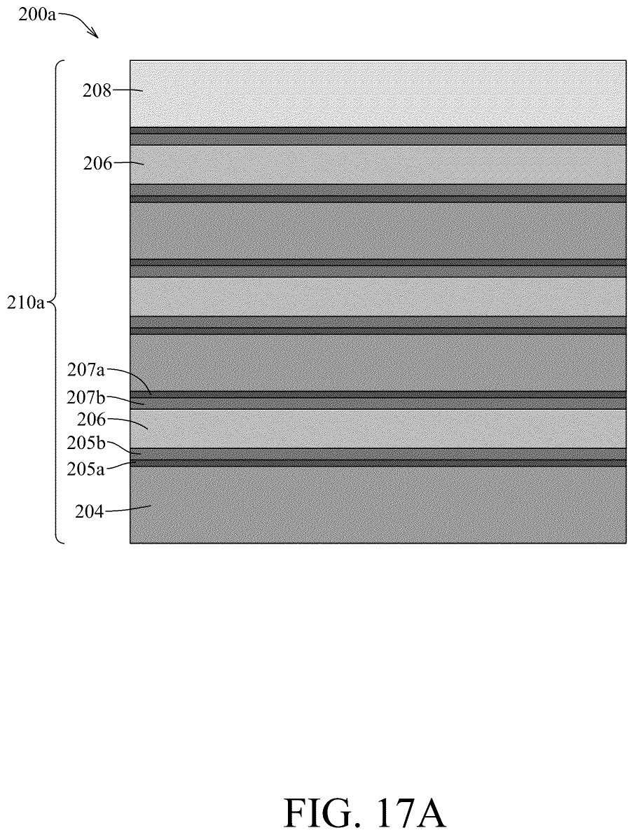

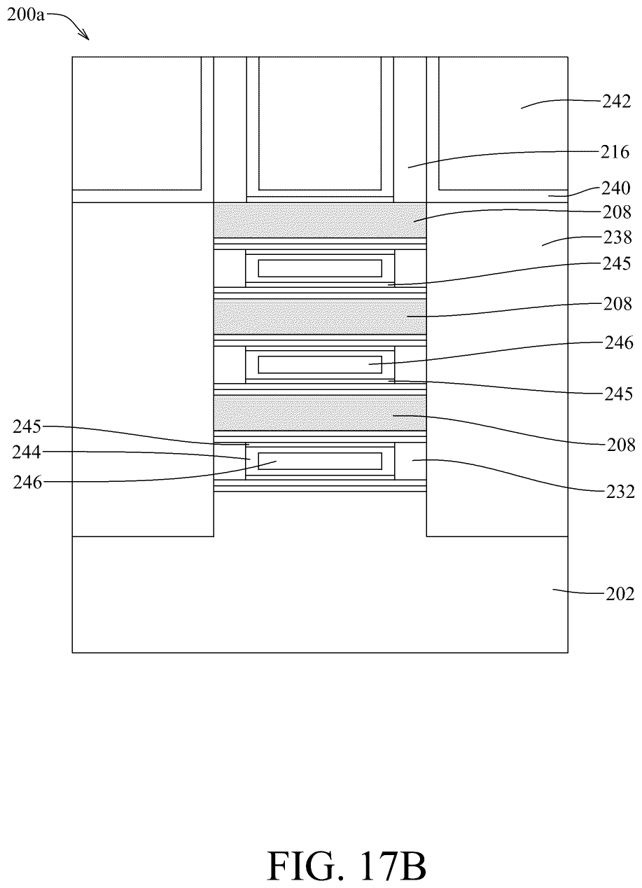

FIGS. 17A-17B schematically illustrate a stage of manufacturing a semiconductor device 200a according to embodiments of the present disclosure. FIG. 17A is a schematic cross sectional view of a semiconductor layer stack for the fin structures in the semiconductor device 200a FIG. 17B is a schematic cross sectional view of the semiconductor device 200a after operation 128.

The semiconductor device 200a is similar to the semiconductor device 200 except that, in semiconductor device 200a, the diffusion barrier layers 205, 207 include two or more sublayers. In the example of FIG. 17A, the first diffusion barrier layer 205 includes a first sublayer 205a and a second sublayer 205b stacked together; and the second diffusion barrier layer 205 include a first sublayer 207a and a second sublayer 207b.

In the first diffusion barrier layer 205, the first sublayer 205a is in contact with or facing the semiconductor channel layer 208 while the second sublayer 205b is in contact with or facing the sacrificial channel layer 206. In some embodiments, the first sublayer 205a and the second sublayer 205b have different doping profiles. It has been observed that a higher dopant concentration provides better diffusion preventing effect and therefore may be desirable to be disposed close to the sacrificial channel layer 206. In some embodiments, the second sublayer 205b includes a higher dopant concentration than the first sublayer 205a. In some embodiments, the first sublayer 205a is formed from doping an epitaxial layer having the same composition as the semiconductor channel layer 208 while the second sublayer 205b is formed from doping an epitaxial layer having the same composition as the sacrificial channel layer 206. For example, the first sublayer 205a includes a doped epitaxial silicon layer and the second sublayer 205b includes a doped epitaxial SiGe layer. In some embodiments, the first sublayer 205a and the second sublayer 205b may be doped by different dopants. In some embodiments, the first sublayer 205a and the second sublayer 205b may have different thicknesses. In some embodiments, one or more additional sublayers may be disposed between the first sublayer 205a and the second sublayer 205b. In some embodiments, dopant concentration profiles of the first sublayer 205a and the second sublayer 205b may be gradient or constant. When one or both of dopant concentration profiles of the first sublayer 205a and the second sublayer 205b are gradient, an average dopant concentration of the second sublayer 205b is higher than that of the first sublayer 205a.

In the second diffusion barrier layer 207, the first sublayer 207a is in contact with or facing the semiconductor channel layer 208 while the second sublayer 207b is in contact with or facing the sacrificial channel layer 206. In some embodiments, the first sublayer 207a and the second sublayer 207b have different doping profiles. In some embodiments, the second sublayer 207b includes a higher dopant concentration than the first sublayer 207a. In some embodiments, the first sublayer 207a is formed from doping an epitaxial layer having the same composition as the semiconductor channel layer 208 while the second sublayer 207b is formed from doping an epitaxial layer having the same composition as the sacrificial channel layer 206. For example, the first sublayer 207a includes a doped epitaxial silicon layer and the second sublayer 207b includes a doped epitaxial SiGe layer. In some embodiments, the first sublayer 207a and the second sublayer 207b may be doped by different dopants. In some embodiments, the first sublayer 205a and the second sublayer 207b may have different thicknesses. In some embodiments, one or more additional sublayers may be disposed between the first sublayer 207a and the second sublayer 207b.

Various embodiments or examples described herein offer multiple advantages over the state-of-art technology. The diffusion barrier layers formed on semiconductor channel layers mitigates diffusions from adjacent sacrificial channel layers, thereby, improving crystallinity of the semiconductor channel layers in the multi-channel devices.

In some aspects, the techniques described herein relate to a method, including: forming a fin stack on a substrate, wherein the fin stack includes: a semiconductor channel layer; a sacrificial channel layer; and a first capping layer disposed between the semiconductor channel layer and the sacrificial channel layer, wherein the first capping layer includes a material different from that of the semiconductor channel layer and the sacrificial channel layer; forming a fin structure from the fin stack; forming a sacrificial gate structure over the fin structure; recess etching the fin structure; forming source/drain regions on opposing sides of sacrificial gate structure, wherein the source/drain regions are connected to the semiconductor channel layer; removing the sacrificial gate structure; removing the sacrificial channel layer; and forming a gate structure around the semiconductor channel layer and the first capping layer.

In some aspects, the techniques described herein relate to a method, including: forming a sacrificial channel layer on a substrate, wherein the sacrificial channel layer includes a first element; forming a semiconductor channel layer on the sacrificial channel layer, wherein the semiconductor channel layer is doped with a second element with an atomic radius smaller than that of the first element; forming a fin structure from a stack including the sacrificial channel layer and the semiconductor channel layer; forming a sacrificial gate structure over the fin structure; forming source/drain regions on two sides of the sacrificial gate structure; selectively removing the sacrificial channel layer and a portion of the semiconductor channel layer doped with the second element from the fin structure; and forming a gate structure around the semiconductor channel layer.

In some aspects, the techniques described herein relate to a semiconductor device, including: a first source/drain region; a second source/drain region; and a channel region connected between the first and second source/drain regions, wherein the channel region includes: a semiconductor channel layer including a first element; a first capping layer disposed on a first surface of the semiconductor channel layer, wherein the semiconductor channel layer is doped with a second element with an atomic radius smaller than that of the first element; a gate dielectric layer formed around the channel region; and a gate electrode layer disposed on the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin stack on a substrate, wherein the fin stack comprises:
a semiconductor channel layer;
a sacrificial channel layer; and
a first capping layer disposed between the semiconductor channel layer and the sacrificial channel layer, wherein the first capping layer comprises a material different from that of the semiconductor channel layer and the sacrificial channel layer;
forming a fin structure from the fin stack;
forming a sacrificial gate structure over the fin structure;
recess etching the fin structure;
forming source/drain regions on opposing sides of sacrificial gate structure, wherein the source/drain regions are connected to the semiconductor channel layer;
removing the sacrificial gate structure;
removing the sacrificial channel layer; and
forming a gate structure around the semiconductor channel layer and the first capping layer.

2. The method of claim 1, wherein forming the fin stack comprises:
forming a first epitaxial grown layer on the semiconductor channel layer; and
doping the first epitaxial grown layer with a first element.

3. The method of claim 2, wherein forming the fin stack further comprises:
forming the semiconductor channel layer on the first capping layer; and
forming a second capping layer on the semiconductor channel layer.

4. The method of claim 3, wherein forming the second capping layer comprises:
forming a second epitaxial grown layer on the semiconductor channel layer; and
doping the second epitaxial grown layer with the first element.

5. The method of claim 4, wherein the first element is one of carbon, boron, and arsenic.

6. The method of claim 2, wherein forming the first epitaxial grown layer comprises doping the first element into a top portion of the semiconductor channel layer.

7. The method of claim 1, wherein the first capping layer comprises:
a first sublayer facing the semiconductor channel layer; and
a second sublayer facing the sacrificial channel layer.

8. The method of claim 7, wherein the first sublayer and the second sublayer have different doping profiles.

9. A method, comprising:
forming a sacrificial channel layer on a substrate, wherein the sacrificial channel layer comprises a first element;
forming a semiconductor channel layer on the sacrificial channel layer, wherein the semiconductor channel layer is doped with a second element with an atomic radius smaller than that of the first element;
forming a fin structure from a stack including the sacrificial channel layer and the semiconductor channel layer;
forming a sacrificial gate structure over the fin structure;
forming source/drain regions on two sides of the sacrificial gate structure;
selectively removing the sacrificial channel layer and a portion of the semiconductor channel layer doped with the second element from the fin structure; and
forming a gate structure around the semiconductor channel layer.

10. The method of claim 9, further comprising forming a first capping layer prior to forming the sacrificial channel layer.

11. The method of claim 10, wherein forming the first capping layer comprises:
forming an epitaxial layer doped with the second element.

12. The method of claim 11, wherein the epitaxial layer is a second semiconductor channel layer formed on the substrate.

13. The method of claim 11, further comprising:
forming the epitaxial layer on the substrate prior to doping the second element.

14. The method of claim 9, wherein the second element has a smaller atomic radius that of silicon or germanium.

15. The method of claim 9, wherein the second element is one of carbon, boron, and arsenic.

16. A semiconductor device, comprising:
a first source/drain region;
a second source/drain region; and
a channel region connected between the first and second source/drain regions, wherein the channel region comprises:
a semiconductor channel layer comprising a first element;
a first capping layer disposed on a first surface of the semiconductor channel layer, wherein the semiconductor channel layer is doped with a second element with an atomic radius smaller than that of the first element;
a gate dielectric layer formed around the channel region; and
a gate electrode layer disposed on the gate dielectric layer.

17. The semiconductor device of claim 16, wherein the channel region further comprises:
a second capping layer disposed on a second surface of the semiconductor channel layer.

18. The semiconductor device of claim 16, wherein the first capping layer comprises an epitaxial layer doped with the second element.

19. The semiconductor device of claim 18, wherein the second element is one of carbon, boron, and arsenic.

20. The semiconductor device of claim 16, further comprising an inner spacer disposed on an end portion of the channel region and between the first source/drain region and the gate dielectric layer, and the inner spacer is in contact with the first capping layer.
